(19) United States
(12) Patent Application Publication
(10) Pub. No.: US 2010/0163965 A1
(43) Pub. Date: Jul. 1, 2010

(54) FLASH MEMORY DEVICE AND MANUFACTURING METHOD OF THE SAME

(76) Inventor: YOUNG JUN KWON, Chungbuk (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/640,600

(22) Filed: Dec. 17, 2009

(30) Foreign Application Priority Data
Dec. 31, 2008 (KR) 10-2008-0138891

(51) Int. Cl. H01L 29/792; H01L 21/336

(52) U.S. Cl. 257/324; 438/261; 257/E29.309; 257/E21.409

(57) ABSTRACT

Disclosed are a flash memory device and a method for manufacturing the same. The flash memory device includes a floating gate including adjacent first and second floating gates on a substrate; first and second select gates respectively on the first and second floating gates; an insulating layer between the first floating gate and the first select gate and between the second floating gate and the second select gate; a drain region at outer sides of the first and second select gates; a source region between the first and second select gates; and a metal contact on each of the drain region and the source region. The select gate can be defined as a self-align structure, and the length of the select gate can be controlled depending on the thickness of the material used to form the select gate.

### CROSS-REFERENCE TO RELATED APPLICATION

This application claims the benefit under 35 U.S.C. §119 of Korean Patent Application No. 10-2008-0138891, filed Dec. 31, 2008, which is hereby incorporated by reference in its entirety.

### BACKGROUND

A flash memory device is a nonvolatile memory device that does not lose data stored therein even if power is turned off. In addition, the flash memory can record, read, and delete data at a relatively high speed.

Accordingly, the flash memory device is widely used for the Bios of a personal computer (PC), a set-top box, a printer, and a network server in order to store data. Recently, the flash memory device is extensively used for digital cameras and portable phones.

In such a flash memory device, a stack gate type semiconductor device employing a floating gate and a semiconductor device having a SONOS (Silicon-Oxide-Nitride-Oxide-Silicon) structure are mainly used.

Electron injection schemes for a memory cell of a flash memory device according to the related art are mainly classified into a Fowler-Nordheim (FN) tunneling scheme and a channel hot electron injection scheme. These two schemes have advantages and disadvantages. The FN tunneling scheme has an advantage of low programming current, but programming time of few ms is required. In addition, a tunnel oxide layer must have thin thickness of 20 to 30 Å, so the FN tunneling scheme has a disadvantage in terms of data retention. Further, the gate bias becomes high, so a high voltage device, a driving circuit, and a pump circuit are necessary.

In contrast, the channel hot electron injection scheme has an advantage of high speed programming of few μs, but high current of several hundreds of μA is required for cell programming, so the channel hot electron injection scheme is not suitable for mobile products due to its high power consumption.

In addition, if a cell having a 1-Tr structure is used, over-erase may occur during the erase operation, so the recovery operation is unnecessarily required. In order to avoid the over-erase, all cells must be controlled to have uniform erase speed.

In addition, in a memory array according to the related art, high voltage is applied to a bit line, so an x-decoder used for selectively applying bias to a specific bit line must include a high voltage transistor that occupies a large area.

FIGS. 1A and 1B are cross-sectional views showing the procedure for manufacturing a flash memory device according to the related art.

FIG. 1A shows a 2-Tr structure memory cell device. In the manufacturing process, when a split select gate for the 2-Tr structure is defined by a photo and etch process, the select gate lengths of the cells may be different from each other (L1≠L2) due to the overlay misalign in the photo process, so a first side (left) cell (A-Cell) of the split may have characteristics different from characteristics of the other side (right) cell (B-Cell) of the split.

Further, for the 2-Tr structure memory cell device, the cell size is significantly enlarged and the manufacturing process is complicated. In addition, due to the low coupling ratio, high bias is required. Thus, the size of a pump circuit provided in a peripheral region is enlarged, so that the chip size is also enlarged.

FIG. 1B shows a 1-Tr ETOX (EPROM tunnel oxide) structure memory device. As shown in FIG. 1B, when the split select gate is defined by the photo and etch process in a state in which a local nitride layer is used as a memory site, the cells may have various nitride lengths (L3≠L4) and select gate lengths (L1≠L2) due to the critical dimension (CD) variation and overlay misalign in the photo process. Therefore, characteristic variation of the left cell (A-Cell) and the right cell (B-Cell) may be increased.

Further, similar to the design of FIG. 1A, the coupling ratio is low and complicated circuits or applications are necessary to solve problems such as over-erase or over program.

### BRIEF SUMMARY

An embodiment provides a structure capable of employing both a channel hot electron injection scheme and an FN tunneling scheme. Thus, the program/erase schemes can be selectively employed depending on applications.

In addition, an embodiment has a 2-Tr structure, so the over-erase problem caused by a select gate can be basically prevented. Thus, unnecessary circuits and unnecessary operations, such as a recovery operation or an iteration operation for preventing the over-erase, may not be required. In addition, since the flash memory device of an embodiment has a high coupling ratio, the program/erase operations can be performed under relatively low bias and low voltage, so that the number of high voltage devices, high voltage driving circuits, and high voltage pumping circuits can be reduced. Therefore, the area of the peripheral region can be significantly reduced.

Further, an embodiment provides a flash memory device and a method for manufacturing the same, which can significantly reduce the cell size as compared with a flash memory having the 2-Tr structure according to the related art, and can significantly reduce an area of a cell peripheral region because the flash memory has the higher coupling ratio as compared with that of the flash memory having the 1-Tr ETOX structure.

In addition, an embodiment provides a flash memory device and a method for manufacturing the same, in which a select gate structure is defined as a self-align structure, so that a length of a select gate is controlled depending on a thickness of the select gate rather than photo and etch processes, thereby ensuring the length of the select gate.

A flash memory device according to an embodiment includes a floating gate including adjacent first and second floating gates on a substrate; first and second select gates respectively on the first and second floating gates; a fourth insulating layer between the first floating gate and the first select gate and between the second floating gate and the second select gate; drain regions at an outer side of both the first select gate and the second select gate, and a source region between the first and second select gates; and a metal contact on each of the drain regions and the source region.

In addition, a method for manufacturing a flash memory device according to an embodiment includes forming a floating gate pattern on a substrate; forming a fourth insulating layer on an entire surface of the substrate including on the floating gate pattern; forming a second polysilicon layer on the fourth insulating layer; forming first and second select gates by patterning the second polysilicon layer; forming drain regions at an outer side of both the first select gate and the second select gate and a source region between the first and second select gates; and forming a metal contact on each of the drain regions and the source region.

### BRIEF DESCRIPTION OF THE DRAWINGS

FIGS. 1A and 1B are cross-sectional views showing a procedure for manufacturing a flash memory device according to a related art;

FIG. 2 is a cross-sectional view showing a flash memory device according to an embodiment;

FIG. 3A is a schematic view showing a cell array of a flash memory device according to a first embodiment;

FIGS. 3B and 3C are cross-sectional views showing the concept of program and erase operations in a flash memory device according to the first embodiment;

FIG. 4A is a schematic view showing a cell array of a flash memory device according to a second embodiment;

FIGS. 4B and 4C are cross-sectional views showing the concept of program and erase operations in a flash memory device according to the second embodiment; and

FIGS. 5 to 17 are cross-sectional views showing a procedure for manufacturing a flash memory device according to an embodiment.

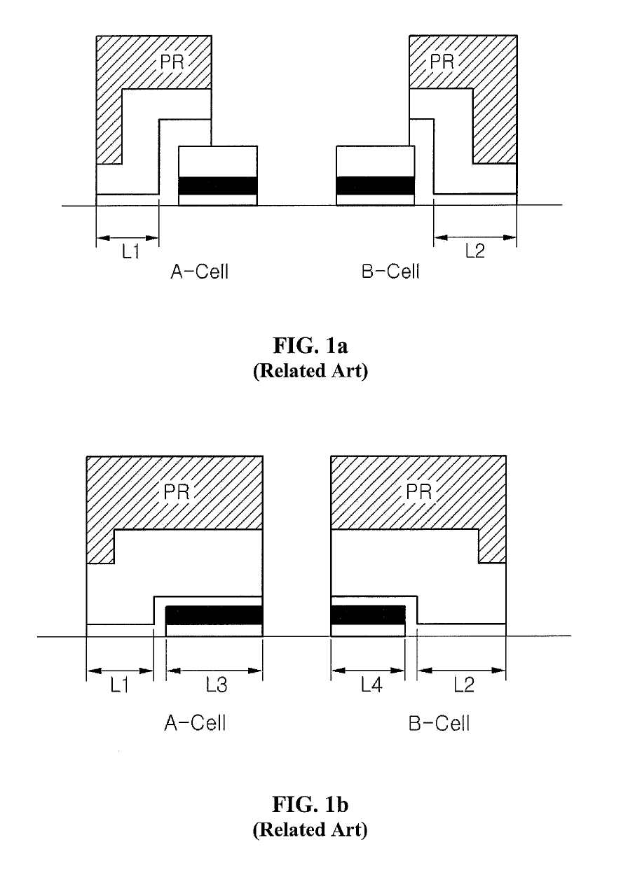

### DETAILED DESCRIPTION

Hereinafter, embodiments of a flash memory device and a method for manufacturing the same will be described with reference to accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, or one or more intervening layers may also be present. In addition, it will also be understood that when a layer is referred to as being ‘between’ two layers, it can be the only layer between the two layers, or one or more intervening layers may also be present.

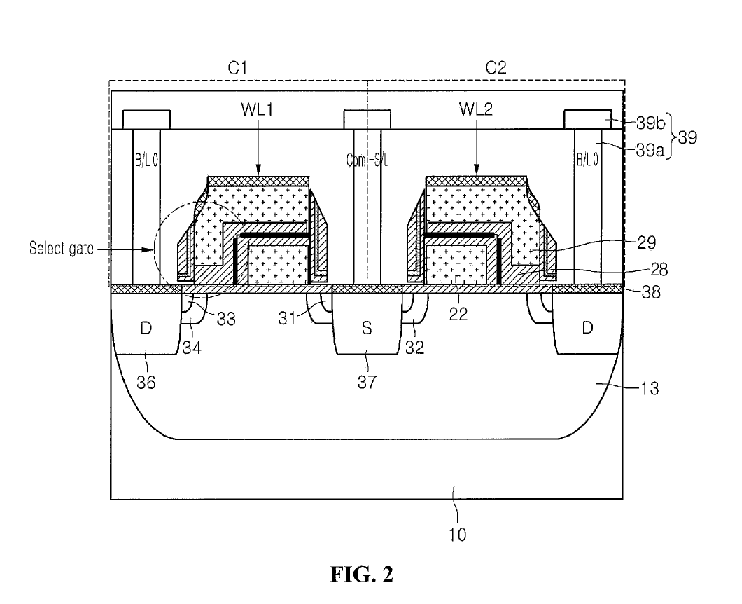

FIG. 2 is a cross-sectional view showing a flash memory device according to an embodiment.

A flash memory device according to an embodiment includes a floating gate 22 on a substrate 10, the floating gate 22 being split to provide first and second floating gates for adjacent memory cells C1 and C2; first and second select gates of a split select gate 29 on the first and second floating gates 22; a fourth oxide layer 28 between the first floating gate 22 and the first select gate 29 and between the second floating gate 22 and the second select gate 29; drain regions 36 at outer sides of the first and second select gates 29, and a source region 37 between the first and second select gates 29; and a metal contact 39a on each of the drain regions and the source region. A first word line signal WL1 can be applied to the first select gate of the cell C1, a second word line signal WL2 can be applied to the second select gate of the cell C2, and a same bit line B/L0 can be connected to the drain regions 36 of both cells C1 and C2, and a common source signal line Com-S/L can be applied to the source region 37. Reference numerals, which are shown in FIG. 2, but not described, will be explained when the manufacturing method for the flash memory device is described.

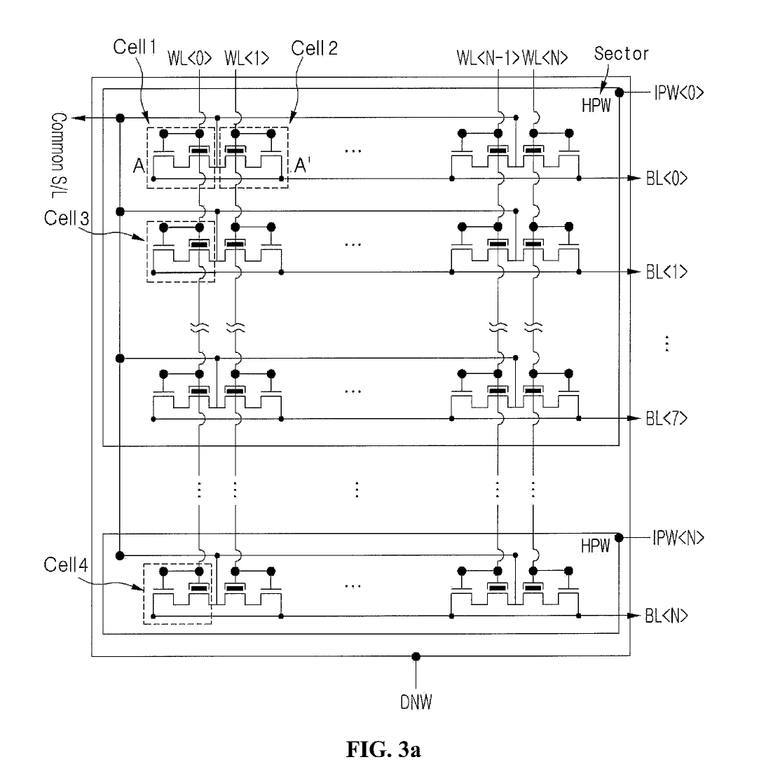

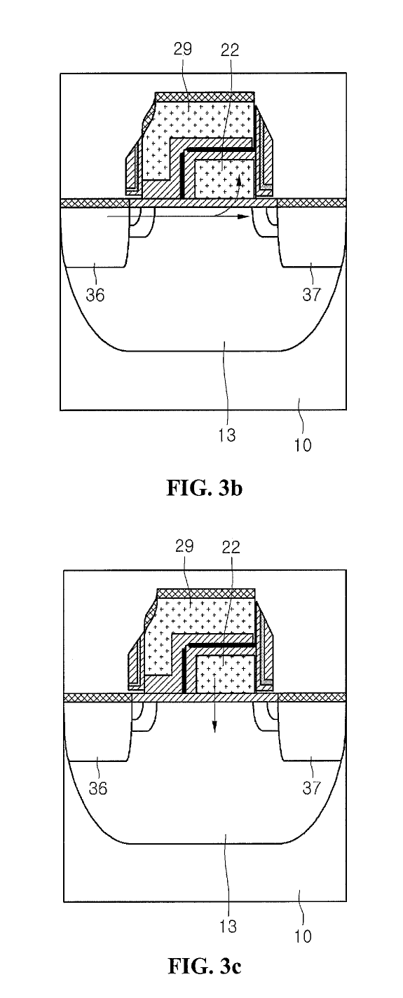

FIG. 3A is a schematic view showing a cell array of a flash memory device according to a first embodiment, and FIGS. 3B and 3C are cross-sectional views showing the concept of program and erase operations in the flash memory device according to the first embodiment.

Hereinafter, the operation of the flash memory device according to the first embodiment will be described with reference to FIGS. 2 and 3A to 3C, and Table 1. FIG. 2 shows a cross-sectional view through line A-A′ of FIG. 3A in accordance with an embodiment of the invention. As illustrated by the schematic diagram of FIG. 3A, each cell includes the two transistor configuration of select gate and floating gate, and the cells are configured in pairs of adjacent cells. The small size can be accomplished by using the split select gate and floating gate configuration of embodiments of the invention to provide the adjacent cell pairs.

A sector is defined by using divided high voltage p-wells (HPWs). The HPWs are isolated from each other by deep n-wells (DNWs). Each HPW can be applied with a signal IPW<0> to IPW<N>. For one embodiment, such as shown in FIG. 3A, a plurality of cells across multiple bit lines and multiple word lines can be included in one sector. Therefore, as described in more detail below, erase operations can be accomplished across large portions of the memory cell region.

Table 1 shows the conditions for program, erase and read operations in the flash memory device according to the first embodiment.

TABLE 1

| | | | PROGRAM | ERASE | READ |
|---|---|---|---|---|---|
| Method | | | Channel Hot | FN tunneling | FN tunneling |
| | | | Electron | | |
| Minimum Oper. Unit | | | Bit | W/L, Sector | Bit |
| Selected Cell | [C 1] | W/L0 | VPP | 0 V | VCC |
| | | Com. S/L | 0 V | Floating | 0 V |
| | | B/L0 | VPP | Floating | Vread |
| | | IPW0 | 0 V | VPP | 0 V |
| Un-selected Cell | Same W/L | W/L0 | VPP | 0 V | VCC |
| | [C 3] | Com. S/L | 0 V | Floating | 0 V |
| | | B/L1 | Floating | Inhibit bias | Floating |
| | | IPW0 | 0 V | VPP | 0 V |
| | Same B/L | W/L1 | 0 V | Inhibit bias | 0 V |
| | [C 2] | Com. S/L | 0 V | Floating | 0 V |
| | | B/L0 | VPP | Floating | Vread |
| | | IPW0 | 0 V | VPP | 0 V |
| | Same W/L | W/L0 | VPP | 0 V | VCC |
| | Different | Com. S/L | 0 V | Floating | 0 V |
| | Sector [C 4] | B/LN | Floating | Inhibit bias | Floating |
| | | IPWN | 0 V/Inhibit | 0 V | 0 V/Inhibit |
| | | | bias/VPP | | bias/VPP |

1) Program Operation

The program operation is achieved through the channel hot electron scheme. In another embodiment, the program operation may be achieved through an FN tunneling scheme. For the program operations, a bias is not applied to unselected HPWs. In the case of a selected cell, VPP is applied to the W/L (word line) connected to the select gate 29 and the B/L (bit line) connected to the drain 36 for the selected cell, and 0V is applied to the common S/L (source line) connected to the source 37 and the HPW (well 13) to generate channel hot electrons. The hot electrons flow from the drain 36 towards the source 37 and into the floating gate 22, as shown in FIG. 3B. The program operation is performed in a unit of bit. Voltages applied to cells C2 and C3 in the same HPW as C1, which are not subject to the program operation, and the voltages applied to cell C4, which is in a different HPW, are shown in Table 1. The VPP refers to pumping bias.

2) Erase Operation

The erase operation is achieved through the FN tunneling scheme. Regarding the bias condition, as shown in Table 1, for a selected cell, 0V is applied to the W/L connected to the select gate 29 and VPP is applied to the HPW (well 13), thereby transferring electrons of the floating gate 22 to the HPW 13 as shown in FIG. 3C. The erase operation can be achieved in a unit of HPW. In addition, the erase operation can be achieved in a unit of sector. In the case of cell C4, 0V is applied to the HPW of the unselected sector to inhibit the unselected cells from being erased. In a further embodiment, inhibit bias is applied to the unselected W/L and B/L. In one embodiment, cells C2 and C3 can be inhibited from being erased during the HPW unit erase by applying inhibit bias to the unselected W/L (e.g., WL<1>) and the unselected bit line B/L (e.g., BL<1>), thereby inhibiting the unselected cells from being erased.

3) Read Operation

The read operation is achieved in the direction the same as the program/erase direction.

Regarding the bias condition, as shown in Table 1, VCC is applied to the selected W/L and a Vread bias is applied to the selected B/L. In the case of cells C2, C3, and C4, the unselected bit lines B/L are floating and 0V is applied to the unselected W/L, so that the unselected cells are not subject to the read operation.

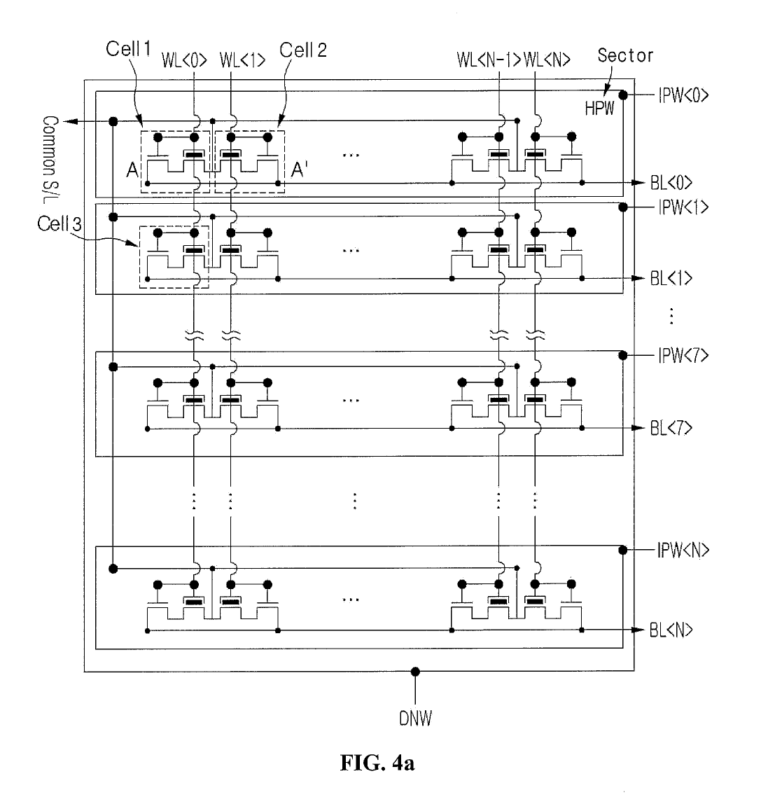

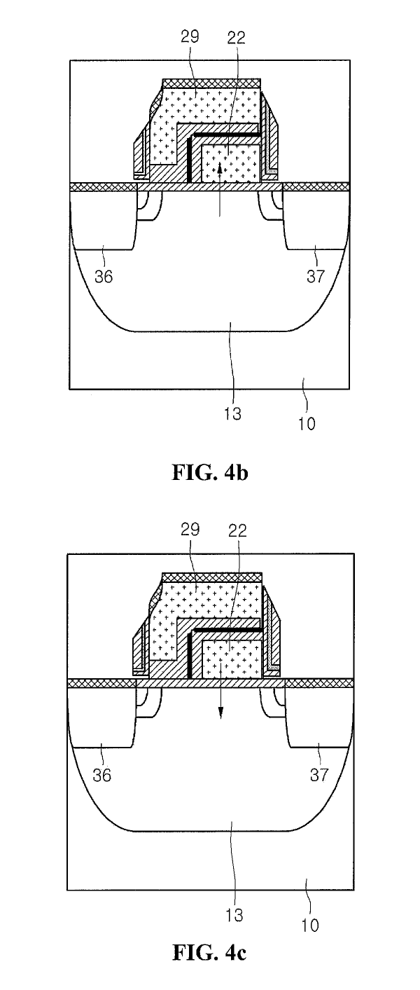

FIG. 4A is a schematic view showing a cell array of a flash memory device according to a second embodiment, and FIGS. 4B and 4C are cross-sectional views showing the concept of program and erase operations in the flash memory device according to the second embodiment.

Hereinafter, the operation of the flash memory device according to the second embodiment will be described with reference to FIGS. 2 and 4A to 4C, and Table 2.

FIG. 2 can represent a cross-sectional view through line A-A′ of FIG. 4A in accordance with an embodiment of the invention. As illustrated by the schematic diagram of FIG. 4A, each cell includes the two transistor configuration of select gate and floating gate, and the cells are configured in pairs of adjacent cells. The small size can be accomplished by using the split select gate and floating gate configuration of embodiments of the invention to provide the adjacent cell pairs.

A sector is defined by using divided HPWs. The HPWs are isolated from each other by DNWs. Each HPW can be applied with a signal IPW<0> to IPW<N>. For one embodiment, such as shown in FIG. 4A, a plurality of cells across multiple word lines can be included in one sector. This can be accomplished using isolated HPWs that are prepared perpendicularly to the word lines W/L. For example, the HPWs can be provided separately for each bit line row.

Table 2 shows the conditions for program, erase and read operations in the flash memory device according to the second embodiment.

TABLE 2

| | | | PROGRAM | ERASE | READ |
|---|---|---|---|---|---|
| Method | | | FN tunneling | FN tunneling | FN tunneling |
| Minimum Oper. | | | Bit | W/L, Sector | Bit |
| Unit | | | | | |
| Selected | [C 1] | W/L0 | VPP | 0 V | VCC |
| Cell | | Com. S/L | Floating | Floating | 0 V |
| | | B/L0 | Floating | Floating | Vread |
| | | IPW0 | 0 V | VPP | 0 V |
| Un- | Same | W/L0 | VPP | 0 V | VCC |
| selected | W/L | Com. S/L | Floating | Floating | 0 V |
| Cell | [C 3] | B/L1 | Floating | Floating | 0 V |
| | | IPW1 | Inhibit bias | 0 V | 0 V |
| | Same | W/L1 | 0 V | Inhibit bias | 0 V |
| | B/L | Com. S/L | 0 V | Floating | 0 V |
| | [C 2] | B/L0 | Floating | Floating | Vread |
| | | IPW0 | 0 V | VPP | 0 V |

1) Program Operation

The program operation is achieved through the FN tunneling scheme. The program operation is performed in a unit of bit. In the program operation, VPP is applied to the selected word line W/L connected to the select gate 29 and 0V is applied to the selected HPW (well 13), thereby injecting electrons into the floating gate 22 of the selected cell, as shown in FIG. 4B. Voltages applied to cells C2 and C3, which are not subject to the program operation, are shown in Table 2. The VPP refers to pumping bias.

2) Erase Operation

The erase operation is achieved through the FN tunneling scheme. Regarding the bias condition, as specified in Table 2, 0V is applied to the W/L and the VPP is applied to the HPW 13 (through e.g., IPW0), thereby transferring electrons of the floating gate 22 to the HPW 13, as shown in FIG. 4C. In the case of cells C2 and C3, 0V is applied to the unselected HPWs and inhibit bias is applied to the unselected W/L, thereby inhibiting the unselected cells from being erased.

3) Read Operation

Regarding the bias condition for the read operation, as shown in Table 2, VCC is applied to the selected W/L and the Vread bias is applied to the selected B/L. In the case of cells C2 and C3, the unselected bit line B/L is floating and 0V is applied to the unselected W/L, so that the unselected cells are not subject to the read operation.

Since the flash memory device according to an embodiment has the cell having the 2-Tr structure, the over-erase may not occur, so complicated circuits employed in a NOR flash memory device to solve the over-erase problem may not be necessary.

In addition, according to the embodiment, the cell size is very small relative to the cell having the 2-Tr EEPROM structure.

Further, since the flash memory device of the embodiment has a high coupling ratio, the program/erase operations can be performed under relatively low bias and low voltage, so that the number of voltage pumping circuits, high voltage devices and decoders can be reduced. Therefore, the chip size can be reduced.

In addition, according to an embodiment, the cell size can be significantly reduced as compared with the cell having the 2-Tr structure.

The cell having the 2-Tr structure represents characteristics sensitive to the length of the select gate. According to the related art, a photo and etch process is performed to control the length of the select gate. In contrast, an embodiment can solve the problems related to the CD and overlay variation of the related art by employing a self-align scheme for the select and floating gates, resulting in superior characteristics in terms of uniformity of cell characteristics.

In addition, according to an embodiment, a peripheral region of a cell can be significantly reduced because the flash memory has a higher coupling ratio as compared with that of the related flash memory having the 2-Tr structure.

Further, the flash memory device according to an embodiment has a higher coupling ratio as compared with that of the related flash memory having the 1-Tr ETOX structure, so that the over-erase problem caused by the select gate can be inhibited. In addition, an embodiment can significantly reduce the area for the pumping circuits and high voltage devices provided in the peripheral region, and iteration and verification procedures can be minimized.

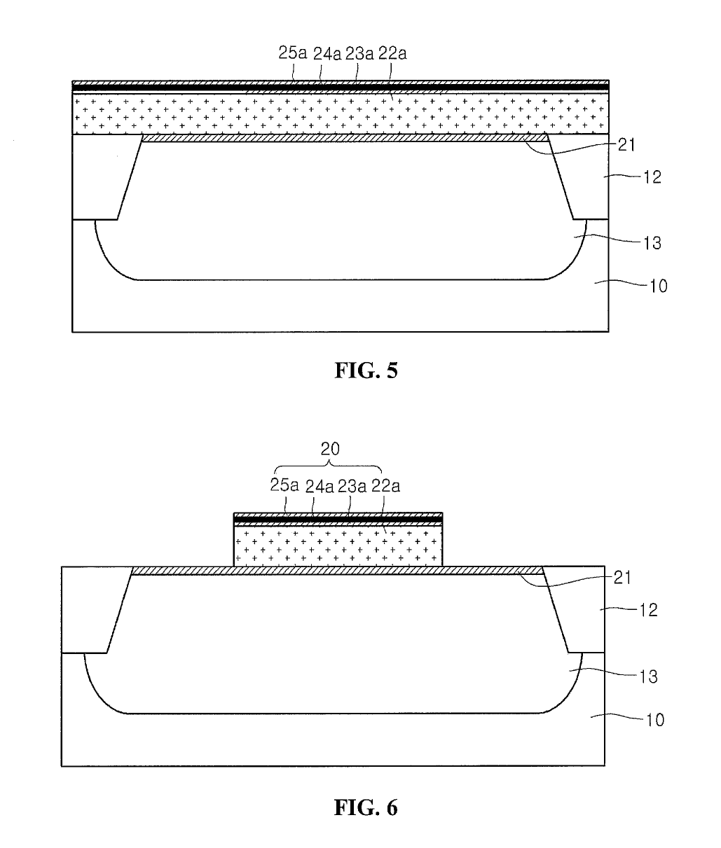

Hereinafter, a method for manufacturing a flash memory device according to an embodiment will be described with reference to FIGS. 5 to 17.

First, referring to FIG. 5, an isolation layer 12 is formed on a substrate 10 to define an active area. According to one embodiment, a pad oxide layer (not shown) can be formed on the active area before performing well processes.

Then, a first ion implantation process is performed on the substrate 10 to form a well area 13. For instance, if the substrate 10 is a P type substrate, N type ions are implanted to form an N type well. According to an embodiment, a second ion implantation process is performed on the substrate 10 having the well area 13 to adjust threshold voltage. In a further embodiment, P-wells can be formed even if the substrate 10 is a P type substrate. According to an embodiment, the well area 13 having the select gate and floating gate stack formed thereon is a high voltage p-well (HPW).

After performing the well implantation processes, the pad oxide layer is removed. Next, a first oxide layer 21, a first polysilicon layer 22a, a second oxide layer 23a, a first nitride layer 24a, and a third oxide layer 25a are sequentially formed on the substrate 10.

For instance, the first oxide layer 21, the second oxide layer 23a, and the third oxide layer 25a can be formed through a thermal oxidation process or a chemical vapor deposition (CVD) process by using SiO₂, but the embodiment is not limited thereto. In addition, the first nitride layer 24a may include SiN, but the embodiment is not limited thereto.

Then, as shown in FIG. 6, a floating gate pattern 20 is formed by patterning the first polysilicon layer 22a, the second oxide layer 23a, the first nitride layer 24a, and the third oxide layer 25a. For instance, a photoresist layer pattern (not shown) that exposes a region where a select gate will be formed later is formed and then an etching process is performed by using the photoresist pattern as an etch mask, thereby forming the floating gate 20.

The etching process can be performed for a period of time in order to etch from the third oxide layer 25a to the first polysilicon layer 22a. In another embodiment, the first polysilicon layer 22a can be etched after etching the third oxide layer 25a to the second oxide layer 23a.

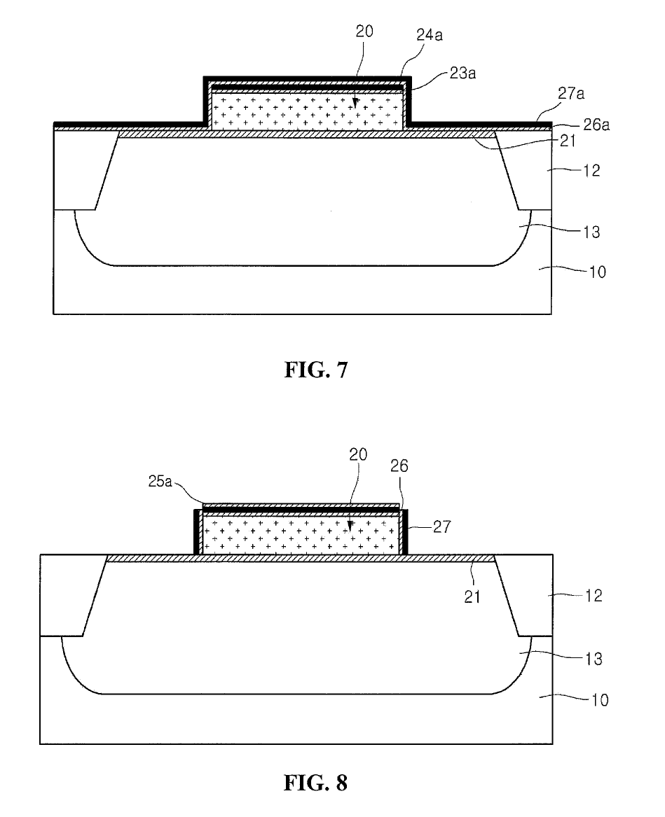

Then, as shown in FIG. 7, a fourth oxide layer 26a and a second nitride layer 27a are formed over the entire surface of the substrate 10 having the floating gate pattern 20. For instance, the second nitride layer 27a and the fourth oxide layer 26a may have thickness equal to that of the first nitride layer 24a and the second oxide layer 23a.

Next, as shown in FIG. 8, a second nitride layer pattern 27 and a fourth oxide layer sidewall 26 are formed at sidewalls of the floating gate pattern 20. For instance, an etch back process can be performed with respect to the second nitride layer 27a and the fourth oxide layer 26a to form the second nitride layer pattern 27 and the fourth oxide layer sidewall 26 at the sidewalls of the floating gate pattern 20.

While the etching process is being performed, the third oxide layer 25a of the floating gate pattern 20 may serve as a buffer layer to protect the first nitride layer 24a.

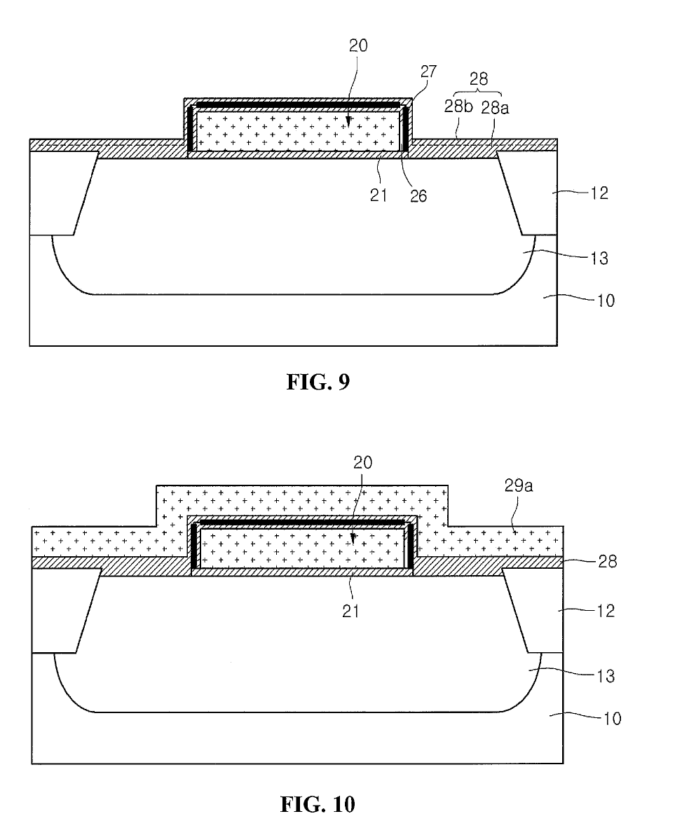

Then, as shown in FIG. 9, a fourth insulating layer 28 is formed on the entire surface of the substrate 10 having the floating gate pattern 20, the fourth oxide layer sidewall 26, and the second nitride layer pattern 27. In one embodiment, the third oxide layer 25a is removed. Then, a deposit oxide layer 28a having thickness of 100 to 200 Å and a thermal oxide layer 28b is formed to provide the fourth insulating layer 28. At this time, the deposit oxide layer 28a can be formed through a CVD process, and the thermal oxide layer 28b can be formed on the deposit oxide layer 28a through a thermal oxidation process. A gate oxide layer of a high voltage transistor formed at a peripheral region (not shown) may be the same as the fourth insulating layer 28, which is used as a select gate oxide layer. In addition, a gate oxide layer of a logic gate of the peripheral region (not shown) can be formed through a dual gate oxidation process, in which the fourth insulating layer 28 in the region for the logic gates is removed, and an oxide layer is formed through a thermal oxidation process.

Next, as shown in FIG. 10, a second polysilicon layer 29a is formed on the fourth insulating layer 28. For instance, the second polysilicon layer 29a, which can be used as both the select gate in the memory cell region (shown) and a gate of the peripheral region (not shown), is formed on the entire surface of the substrate 10 formed with the fourth oxide layer 28.

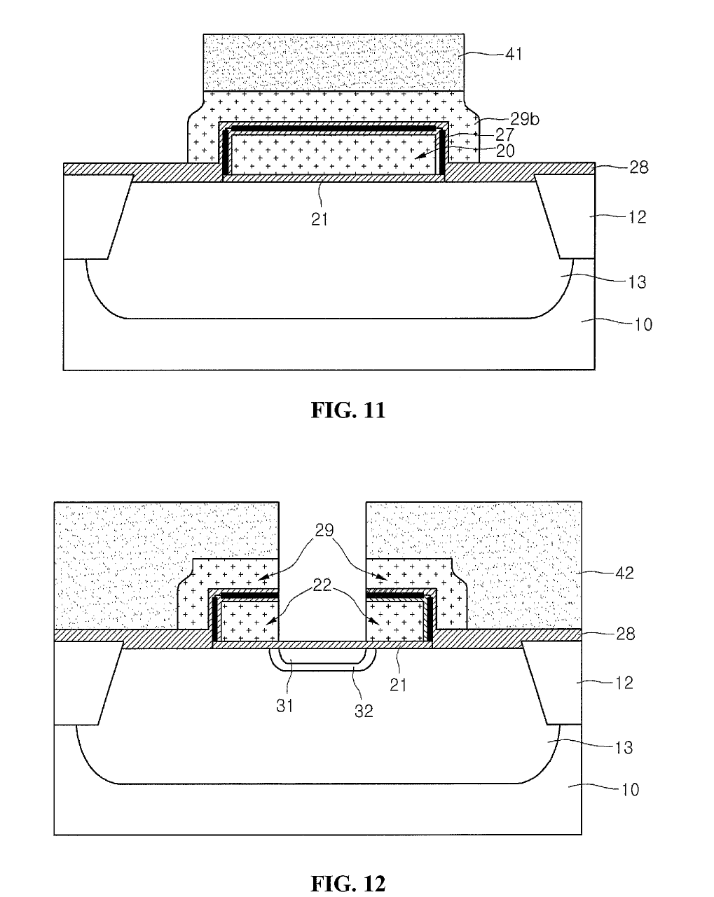

Then, as shown in FIG. 11, a first photoresist layer pattern 41 is formed on the second polysilicon layer 29a, and a second polysilicon layer pattern 29b is formed through an etching process by using the first photoresist layer pattern 41 as an etch mask. The second polysilicon layer pattern 29b covers the region where the select gate will be formed later. The outer sides of the second polysilicon layer pattern 29b can include polysilicon residue re-deposited at the sidewalls during the etching process using the first photoresist layer pattern 41 as the etch mask.

At this time, the length of the select gate is determined depending on the thickness of the second polysilicon layer 29a. Thus, variation of the length of the select gate can be minimized, improving uniformity of the cells.

Then, as shown in FIG. 12, the first photoresist layer pattern 41 is removed and a second photoresist layer pattern 42 is formed on the entire surface of the substrate 10. The second photoresist layer pattern 42 can be arranged to expose the second polysilicon layer pattern 29b corresponding to where a source region is to be formed. Then, a split first and second select gate 29 is formed by etching the second polysilicon layer pattern 29b.

According to an embodiment, while the first and second select gates 29 are being formed by patterning the second polysilicon layer pattern 29b, a further etching can be conducted such that the floating gate pattern 20 is etched to form a split first and second floating gate 22.

Then, an ion implantation process is performed for the source (common source) by using the second photoresist layer pattern 42 as an ion implantation mask. For instance, according to an embodiment, when the ion implantation process is performed for the source, a halo ion implantation region 32 and a lightly doped drain (LDD) ion implantation region 31 can be formed to improve HCI (hot carrier injection) efficiency.

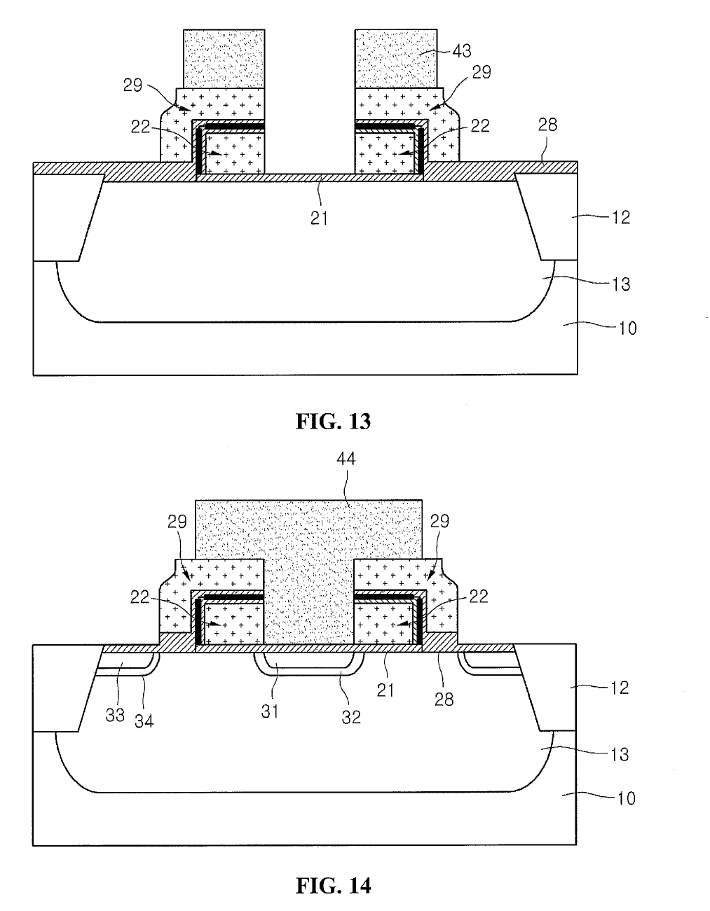

Meanwhile, FIG. 13 shows another embodiment to form the split first and second select gates 29 and the split first and second floating gates 22.

Referring to FIG. 13, a third photoresist layer pattern 43 is formed that blocks where the select gate is to be formed. Then, the etching process is performed to form the first and second select gates 29 and the first and second floating gates 22. The halo and LDD regions for the source region and the drain regions can be formed simultaneously by using the third photoresist layer pattern 43 as an ion implantation mask.

Referring to FIG. 14, after the step shown in FIG. 12, the second photoresist layer pattern 42 can be removed, and a fourth photoresist layer pattern 44 that exposes the substrate 10 at the drain regions is formed. Then, a halo ion implantation region 34 and an LDD ion implantation region 33 are formed using the fourth photoresist layer pattern 44 as an ion implantation mask.

At this time, according to an embodiment, the ion implantation process for the drains of the cell can be performed simultaneously with the LDD ion implantation process for a transistor provided in the peripheral region. In addition, a double doped drain (DDD) ion implantation process can be performed for the source/drain of the cell and the source/drain of the high voltage transistor provided in the peripheral region.

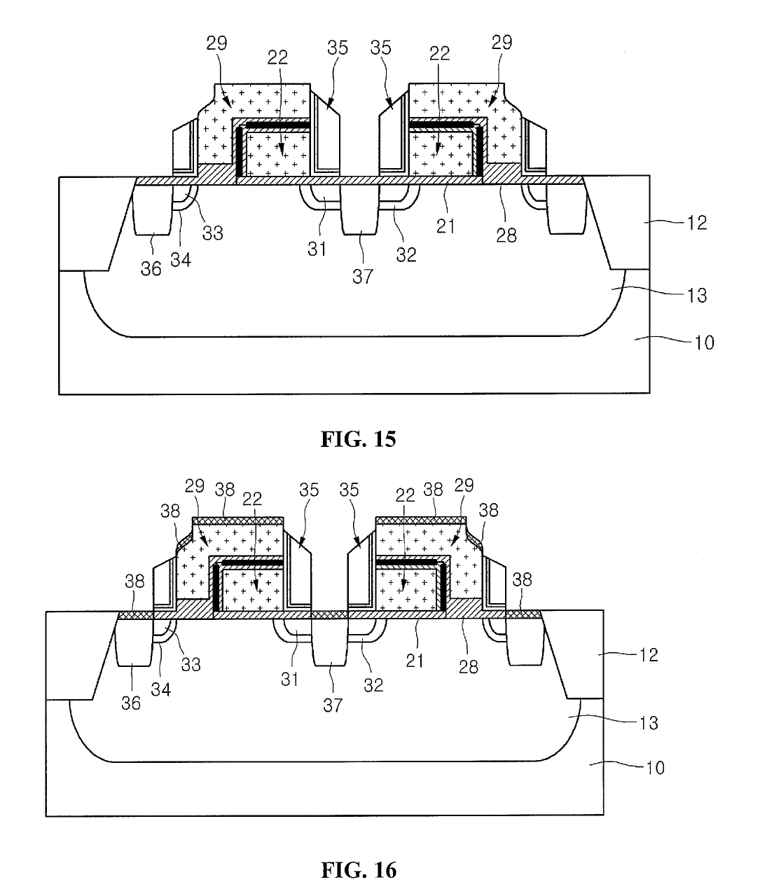

Next, as shown in FIG. 15, a drain region 36 is formed at outer sides of the split first and second select gates 29, and a source region 37 is formed between the split first and second select gates 29 after removing the fourth photoresist layer pattern 44.

For instance, according to an embodiment, a spacer 35 can be formed at sidewalls of the select gate 29/floating gate 22 structures. Then, the ion implantation process is performed with respect to the source/drain of the cells, thereby forming the source region 37 and the drain region 36. At this time, according to an embodiment, the ion implantation process for the source/drain of the transistors provided in the peripheral region (not shown) can be simultaneously performed.

According to certain embodiments, the spacer 35 may have an ONO (Oxide-Nitride-Oxide) structure or an ON (Oxide-Nitride) structure.

Then, referring to FIG. 16, a salicide process is performed. For instance, after removing the first oxide layer 21 from the source region 37 and the drain region 36, a metal layer, such as a cobalt (Co) layer, is formed on the entire surface of the substrate 10. After that, salicide layers 38 are formed on the source region 37, the drain region 36 and the select gate 29 through a heat treatment process.

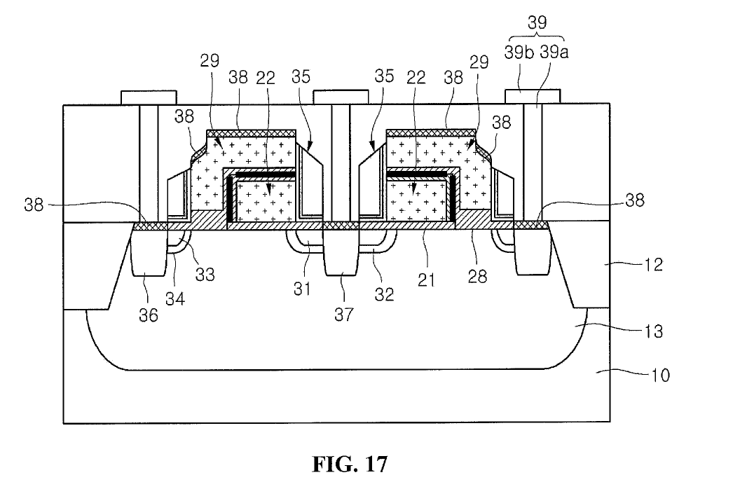

Next, referring to FIG. 17, a back end process is performed to form a metal line 39 including a metal contact 39a and an interconnection line 39b on the drain regions 36 and the source region 37.

Since the flash memory device in accordance with an embodiment has the cell having the 2-Tr structure, the over-erase may not occur, so complicated circuits employed in a NOR flash memory device to solve the over-erase problem may not be necessary.

In addition, according to an embodiment, the cell size is very small relative to the cell having the 2-Tr EEPROM structure.

Further, since the flash memory device of embodiments has a high coupling ratio, the program/erase operations can be performed under relatively low bias and low voltage, so that the number of voltage pumping circuits, high voltage devices and decoders can be reduced. Therefore, the chip size can be reduced.

In addition, according to an embodiment, the cell size can be significantly reduced as compared with the cell having the 2-Tr structure.

The cell having the 2-Tr structure represents characteristics sensitive to the length of the select gate. According to the related art, the photo and etch process is performed to control the length of the select gate. However, an embodiment can solve the problems related to the CD and overlay variation by employing a self-align scheme where the floating gate is etched with the select gate, providing superior characteristics in terms of uniformity of cell characteristics.

In addition, according an the embodiment, the peripheral region of the cell can be significantly reduced because the flash memory has the higher coupling ratio as compared with that of the flash memory having the 2-Tr structure.

Further, the flash memory device according to an embodiment has a higher coupling ratio as compared with that of the flash memory having the 1-Tr ETOX structure, so that the over-erase problem caused by the select gate can be inhibited. In addition, embodiments can significantly reduce the area for the pumping circuits and high voltage devices provided in the peripheral region, minimizing the need to perform iteration and verification procedures.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A flash memory device comprising:
a first floating gate and a second floating gate adjacently disposed on a substrate;
a first select gate on the first floating gate and a second select gate on the second floating gate;
an insulating layer between the first floating gate and the first select gate and between the second floating gate and the second select gate;
a drain region at outer sides of the first and second select gates;
a source region between the first and second select gates, wherein an inner side surface of the first floating gate is aligned with an inner side surface of the first select gate and an inner side surface of the second floating gate is aligned with an inner side surface of the second select gate; and
a metal contact on each of the drain region and the source region.

2. The flash memory device of claim 1, further comprising:
an oxide layer pattern and a nitride layer pattern on outer sidewalls of the first and second floating gates, wherein the oxide layer pattern and the nitride layer pattern are disposed between the floating gate and the insulating layer.

3. The flash memory device of claim 1, further comprising a halo ion implantation region and an LDD ion implantation region formed in the substrate between the first and second select gates.

4. The flash memory device of claim 1, wherein the insulating layer is further formed between the first and second select gates and the substrate.

5. The flash memory device of claim 1, wherein the fourth insulating layer serves as a gate insulating layer for the first and second select gates.

6. The flash memory device of claim 1, wherein a program operation of the flash memory device is carried out through a channel hot electron scheme.

7. The flash memory device of claim 1, wherein a program operation of the flash memory device is carried out through a FN tunneling scheme.

8. A method for manufacturing a flash memory device, the method comprising:
forming a floating gate pattern on a substrate;
forming an insulating layer on an entire surface of the substrate formed with the floating gate pattern;
forming a second polysilicon layer on the insulating layer;
forming first and second select gates by patterning the second polysilicon layer, the first and second select gates being adjacent to each other;
forming a drain region at outer sides of the first and second select gates;
forming a source region between the first and second select gates; and
forming a metal contact on each of the drain region and the source region.

9. The method of claim 8, wherein the forming of the floating gate pattern on the substrate comprises:
sequentially forming a first oxide layer, a first polysilicon layer, a second oxide layer, a first nitride layer, and a third oxide layer on the substrate; and
patterning the first polysilicon layer, the second oxide layer, the first nitride layer, and the third oxide layer to form the floating gate pattern.

10. The method of claim 9, further comprising:
forming first and second floating gates below the first and second select gates by etching the floating gate pattern during the patterning of the second polysilicon layer.

11. The method of claim 8, further comprising forming a fourth oxide layer pattern and a second nitride layer pattern on outer sidewalls of the floating gate pattern after forming the floating gate pattern.

12. The method of claim 11, wherein the forming of the fourth oxide layer pattern and the second nitride layer pattern:
forming a second nitride layer and a fourth oxide layer on an entire surface of the substrate including on the floating gate pattern after forming the floating gate pattern; and
performing an etch back process with respect to the second nitride layer and the fourth oxide layer.

13. The method of claim 12, wherein the floating gate pattern comprises a first oxide layer, a first polysilicon layer, a second oxide layer, a first nitride layer, and a third oxide layer, wherein the second nitride layer and the fourth oxide layer have thickness equal to thickness of the first nitride layer and the second oxide layer.

14. The method of claim 8, wherein the forming of the first and second select gates comprises:
etching the second polysilicon layer through a self-align scheme.

15. The method of claim 8, further comprising:
simultaneously forming a peripheral gate poly during the forming of the first and second select gates.

16. The method of claim 8, further comprising:
simultaneously performing an ion implantation process on a source and a drain of a transistor provided in a peripheral region during the forming of the drain region at outer sides of the first and second select gates.
